(19) United States
(12) Patent Application Publication
(10) Pub. No.: US 2014/0319681 A1
(43) Pub. Date: Oct. 30, 2014

(54) SEMICONDUCTOR PACKAGE INCLUDING SOLDER BALL

(71) Applicant: SAMSUNG ELECTRONICS CO., LTD., Suwon-si (KR)

(72) Inventors: Du MAOHUA, Suzhou City (CN); Zhao YIFAN, Suzhou City (CN)

(73) Assignee: SAMSUNG ELECTRONICS CO., LTD., Suwon-si (KR)

(21) Appl. No.: 14/253,126

(22) Filed: Apr. 15, 2014

(30) Foreign Application Priority Data
Apr. 24, 2013 (CN) 201310144193.3
Feb. 19, 2014 (KR) 10-2014-0019209

(51) Int. Cl. H01L 23/498; H01L 23/00

(52) U.S. Cl. CPC H01L 23/49816; H01L 24/14; H01L 2224/1405
USPC 257/738

(57) ABSTRACT

There is provided a semiconductor package comprising: a chip mounted on a substrate; and at least one solder ball formed under the substrate, wherein the solder ball comprises: a solder layer; a shell surrounded by the solder layer; and a phase change material contained in the shell.

### CROSS-REFERENCE TO RELATED APPLICATIONS

This application claims from Chinese Patent Application No. 201310144193.3, filed on Apr. 24, 2013, in State Intellectual Property Office (SIPO) of the People's Republic of China and Korean Patent Application No. 10-2014-0019209, filed on Feb. 19, 2014, in the Korean Intellectual Property Office, the disclosures of which are incorporated herein in their entirety by reference

### BACKGROUND

The inventive concept relates to a semiconductor package, and more particularly, to a semiconductor package including solder balls.

A semiconductor package may include solder balls. The solder balls may be formed of a solder alloy having higher thermal conductivity than that of epoxy molding compound (EMC). Therefore, heat generated by a chip easily flows to a wiring substrate through solder balls so that a user of a host apparatus mounted with a semiconductor package and a wiring substrate, for example, a portable terminal may experience inconvenience with lapse of time.

### SUMMARY

An inventive concept provides a semiconductor package including solder balls capable of efficiently managing heat generated by a chip.

According to an aspect of an exemplary embodiment of the inventive concept, there is provided a semiconductor package which may include: a chip mounted on a substrate; and at least one first solder ball formed under the substrate, wherein the solder ball includes: a solder layer; a shell surrounded by the solder layer; and a phase change material contained in the shell.

The shell may be a plastic shell or a metal shell. The shell may be a hollow shell. An inside of the shell may be formed of a grid structure, and the phase change material may be formed in or across the grid structure of the shell.

The shell may be formed of a plurality of metal layers surrounding the phase change material layer. The phase change material may be formed of at least one selected from a group consisting of polyethylene glycol, methylene diphenyl diisocyanate, and polyethylene glycol copolymer.

An encapsulation layer for sealing up the chip may be formed on the substrate. A wiring substrate may be further arranged under the substrate, and the chip mounted on the substrate may be electrically connected to the wiring substrate through the first solder ball.

An interpose substrate may be further arranged on the substrate, the chip may be mounted on the interpose substrate, at least one second solder ball electrically connected to the substrate may be formed under the interpose substrate, and the chip mounted on the interpose substrate may be electrically connected to the wiring substrate through the second solder ball and the first solder ball.

At least one through via electrically connected to the first solder ball may be formed in the substrate. The chip may be a stack type chip in which a plurality of separate chips may be stacked on the substrate, and the separate chips may be connected to each other by at least one through via. The chip may be formed of a first chip mounted on the substrate and a second chip horizontally separated from the first chip to be mounted.

According to an aspect of another exemplary embodiment of the inventive concept, there is provided a semiconductor package which may include: a first chip mounted on a first substrate; at least one first solder ball formed on the first substrate; a second substrate arranged on the first solder ball; a second chip mounted on the second substrate; and at least one second solder ball formed on a rear surface of the first substrate, wherein at least one solder ball among the first solder ball and the second solder ball may include: a solder alloy layer; a shell surrounded by the solder alloy layer; and a phase change material layer positioned in the shell.

A first encapsulation layer for sealing up the first chip may be formed on the first substrate, and a second encapsulation layer for sealing up the second chip may be formed on the second substrate.

A wiring substrate may be further arranged under the first substrate, and the first chip and the second chip mounted on the first substrate and the second substrate, respectively, may be electrically connected to the wiring substrate through the first and second solder balls.

### BRIEF DESCRIPTION OF THE DRAWINGS

Exemplary embodiments of the inventive concept will be more clearly understood from the following detailed description taken in conjunction with the accompanying drawings, in which:

FIG. 1 is a cross-sectional view illustrating a semiconductor package according to an embodiment of the inventive concept;

FIG. 2 is a cross-sectional view illustrating a semiconductor package according to an embodiment of the inventive concept;

FIG. 3 is a cross-sectional view illustrating a solder ball that may be used for a semiconductor package according to an embodiment of the inventive concept;

FIG. 4 is a cross-sectional view illustrating a solder ball that may be used for a semiconductor package according to an embodiment of the inventive concept;

FIG. 5 is a cross-sectional view illustrating solder balls that may be used for a semiconductor package according to an embodiment of the inventive concept;

FIG. 6 is a cross-sectional view illustrating heat flow of a semiconductor package according to an embodiment of the inventive concept;

FIG. 7 is a schematic diagram illustrating a common usage state of a semiconductor package using solder balls according to an embodiment of the inventive concept;

FIG. 8 is a schematic diagram illustrating a state of a semiconductor package using solder balls according to an embodiment of the inventive concept after phase changes are generated in phase change material layers in the solder balls;

FIG. 9 is a flowchart illustrating a heat management method of a semiconductor package according to an embodiment of the inventive concept;

FIG. 10 is a view illustrating temperature changes of chips and wiring substrates having solder balls according to a conventional art and an embodiment of the inventive concept based on service (usage) time;

FIG. 11 is a cross-sectional view illustrating a semiconductor package according to an embodiment of the inventive concept;

FIG. 12 is a cross-sectional view illustrating a semiconductor package according to an embodiment of the inventive concept;

FIG. 13 is a cross-sectional view illustrating a semiconductor package according to an embodiment of the inventive concept;

FIG. 14 is a cross-sectional view illustrating a semiconductor package according to an embodiment of the inventive concept;

FIG. 15 is a cross-sectional view illustrating a semiconductor package according to an embodiment of the inventive concept;

FIG. 16 is a schematic diagram illustrating a configuration of a package module using a semiconductor package according to an embodiment of the inventive concept;

FIG. 17 is a schematic diagram illustrating a configuration of a card using a semiconductor package according to an embodiment of the inventive concept; and

FIG. 18 is a schematic diagram illustrating a configuration of an electronic system using a semiconductor package according to an embodiment of the inventive concept.

### DETAILED DESCRIPTION OF THE EXEMPLARY EMBODIMENTS

The inventive concept will now be described more fully with reference to the accompanying drawings, in which exemplary embodiments of the inventive concept are shown. The same elements in the drawings are denoted by the same reference numerals and a repeated explanation thereof will not be given. The inventive concept may, however, be embodied in many different forms and should not be construed as limited to the embodiments set forth herein. Rather, these embodiments are provided so that this disclosure will be thorough and complete, and will fully convey the scope of the inventive concept to one of ordinary skill in the art. In the drawings, the thickness of layers and regions are exaggerated for clarity.

It will also be understood that when an element is referred to as being “on” another element, it can be directly on the other element, or intervening elements may also be present. On the other hand, when an element is referred to as being “immediately on” or as “directly contacting” another element, it can be understood that intervening elements do not exist. Other expressions describing a relationship between elements, for example, “between” and “directly between” may be interpreted as described above.

It will be understood that, although the terms first and second, etc., may be used herein to describe various elements, these elements should not be limited by these terms. These terms are only used to distinguish one element from another element. For example, a first element may be named a second element and similarly a second element may be named a first element without departing from the scope of the inventive concept.

In addition, relative terms such as “on” or “above” and “under” or “below” may be used for describing a relationship between certain elements and other elements as illustrated in the drawings. The relative terms may be understood to include other directions of a device in addition to directions described in the drawings. For example, when the device is turned over in the drawings, elements described to exist on upper surfaces of other elements have directions on lower surfaces of the other elements. Therefore, the term “on” may include both of the directions “under” and “on” based on a specific direction of the drawings. When the device is in another direction (rotates at 90 degrees with respect to another direction), relative descriptions used in the inventive concept may be interpreted in accordance with the above.

Unless otherwise defined, terms “include” and “have” are for representing that characteristics, numbers, steps, operations, elements, and parts described in the specification or a combination of the above exist. It may be interpreted that one or more other characteristics, numbers, steps, operations, elements, and parts or a combination of the above may be added.

The embodiments of the inventive concept will be described with reference to the drawings that schematically illustrate ideal embodiments of the inventive concept. In the drawings, in accordance with, for example, a manufacturing technology and/tolerance, transformations of an illustrated shape may be expected. Therefore, the embodiments of the inventive concept must not be interpreted as being limited to a specific shape of a region illustrated in the inventive concept and must include a change in shape caused by manufacturing processes. In addition, the embodiments described hereinafter may be implemented by combining at least one.

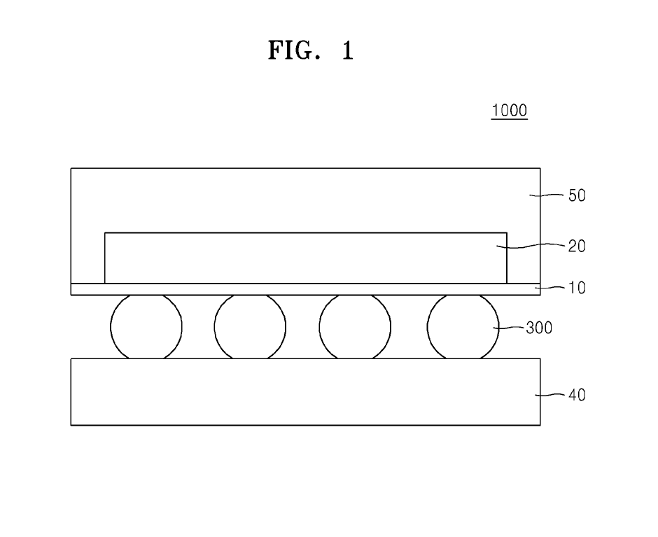

FIG. 1 is a cross-sectional view illustrating a semiconductor package according to an embodiment of the inventive concept.

Specifically, a semiconductor package 1000 according to an embodiment of the inventive concept may be a ball grid array package. The semiconductor package 1000 may include a substrate 10, a chip 20 mounted on the substrate 10, an encapsulation layer 50 for sealing up or encapsulating the chip 20, solder balls 300 formed on a rear surface of the substrate 10, and a wiring substrate 40 on which the solder balls 300 are mounted. The chip 20 may be a flip-chip bonded to the substrate 10. The semiconductor package 1000 is illustrated as including the wiring substrate 40, however, may not include the wiring substrate 40.

The substrate 10 and the wiring substrate 40 may be a printed circuit board (PCB). The solder balls 300 may be arranged between the chip 20 mounted on the substrate 10 and the wiring substrate 40. The solder balls 300 may electrically connect the chip 20 mounted on the substrate 10 and the wiring substrate 40. The solder balls 300 may extend a function of the chip 20 to the outside. The solder balls 300 may include phase change material layers described later in detail to absorb heat generated by the chip 20. The encapsulation layer 50 may be an epoxy molding compound (EMC).

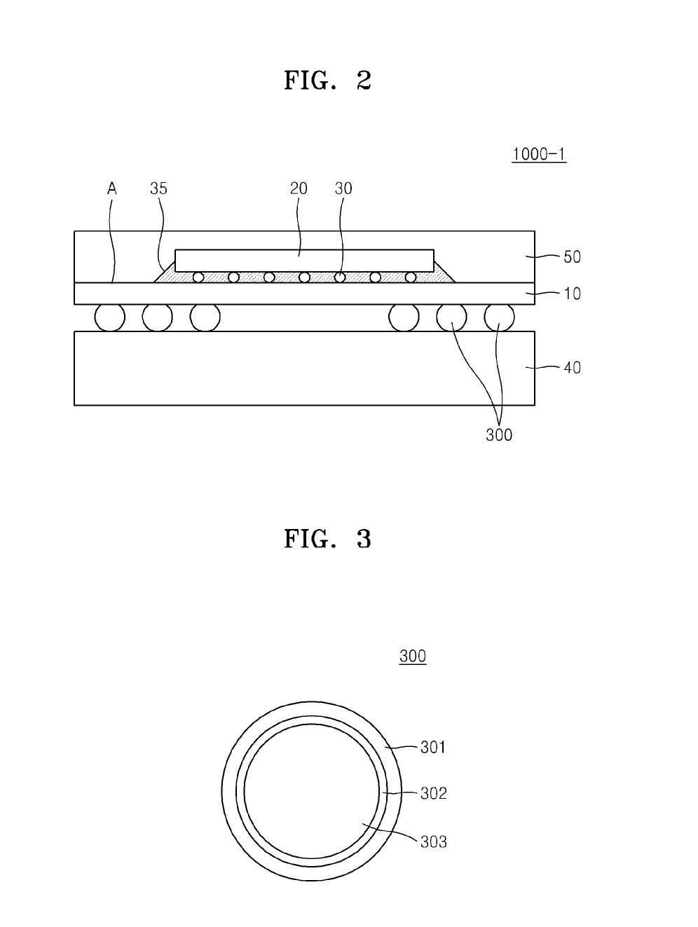

FIG. 2 is a cross-sectional view illustrating a semiconductor package according to an embodiment of the inventive concept.

Specifically, a semiconductor package 1000-1 of FIG. 2 is the same as the semiconductor package 1000 of FIG. 1 except that a chip 20 is connected to a substrate 10 by a plurality of bumps 30 and an underfill 35 is filled between the bumps 30.

In the semiconductor package 1000-1, the chip 20 may be mounted on the substrate 10 through the bumps 30. The semiconductor package 1000-1 may include the underfill 35 also to fill a space between the chip 20 and the substrate 10.

The semiconductor package 1000-1 may include an encapsulation layer 50 for sealing up or encapsulating the chip 20 mounted on the substrate 10 and solder balls 300 formed under the substrate 10. The solder balls 300 may absorb heat generated by the chip 20 as described above.

The bumps 30 may mean conductive protrusions used for flip-chip bonding the chip 20 to the substrate 10. The bumps 30 may be formed of a metal material such as solder, gold, and copper.

FIG. 3 is a cross-sectional view illustrating a solder ball that may be used for a semiconductor package according to an embodiment of the inventive concept.

Specifically, FIG. 3 is a schematic block diagram of a solder ball 300 which may be the solder ball illustrated in FIGS. 1 and 2. The solder ball 300 according to the embodiment of the inventive concept may include a solder alloy layer 301, a shell 302 surrounded by the solder alloy layer 301, and a phase change material 303 formed in the shell 302.

The solder alloy layer 301 may be formed of materials commonly used in the art. For example, the solder alloy layer 301 may be formed of at least one of tin (Sn)-gold (Ag)-copper (Cu) based metal, Sn—Ag based metal, Sn-bismuth (Bi) based metal, Sn—Cu based metal, and Sn-zinc (Zn) based metal. The solder alloy layer 301 according to the present embodiment is not limited to the above materials. For example, the solder alloy layer 301 does not have to be formed of any alloy.

As illustrated in FIG. 3, the shell 302 may be a hollow shell that maintains a shape of the phase change material 303 filled in the shell 302.

The shell 302 may be a plastic shell. That is, the shell 302 may be formed of plastic. The shell 302 may be a metal shell. A component of the metal shell is not limited. However, gold, silver, nickel, zinc, tin, aluminum chrome, antimony, and copper may be used as the metal shell. The metal shell may be formed of at least one of the above metals. According to the present embodiment, the shell 302 may be formed of a metal material such as copper or aluminum.

The phase change material 303 contained in the shell 302 may absorb heat generated by a chip so that the heat may be transmitted through the solder alloy layer 301 and the shell 302. The phase change material 303 in the shell 302 may change a physical state in a predetermined temperature range. For example, in a case where a solid-liquid phase change occurs, when the phase change material 303 is heated at melting temperature and absorbs and stores a large amount of latent heat while being melt, the phase change material 303 is changed from a solid to a liquid. The stored heat is discharged to an external air in the predetermined temperature range when the phase change material 303 is cooled so that inverse transformation from a liquid to a solid occurs.

In a process of two stage changes (that is, the solid-liquid phase change and a liquid-solid phase change), stored or discharged energy may be latent heat of a phase change. Temperature of the phase change material 303 is hardly changed before a physical state thereof is changed so that the phase change is completed. Therefore, the phase change material 303 may have a wide temperature platform. Therefore, although the temperature of the phase change material 303 is not changed, an amount of absorbed or discharged latent heat may be very large.

According to an embodiment of the inventive concept, the phase change material 303 may be formed of a material having a low phase change point and high pyrolysis temperature, for example, polyethylene glycol, methylene diphenyl diisocyanate, and/or polyethylene glycol copolymer. However, the inventive concept is not limited thereto and one of ordinary skill in the art may use other materials as appropriate phase change materials.

Although the solder ball 300 is structured such that the phase change material 303 is contained in the shell 302 surrounded by the solder alloy layer 301, the inventive concept is not limited thereto, and may take a different structure, for example, which does not have at least one of the shell 302 and the solder alloy layer 301.

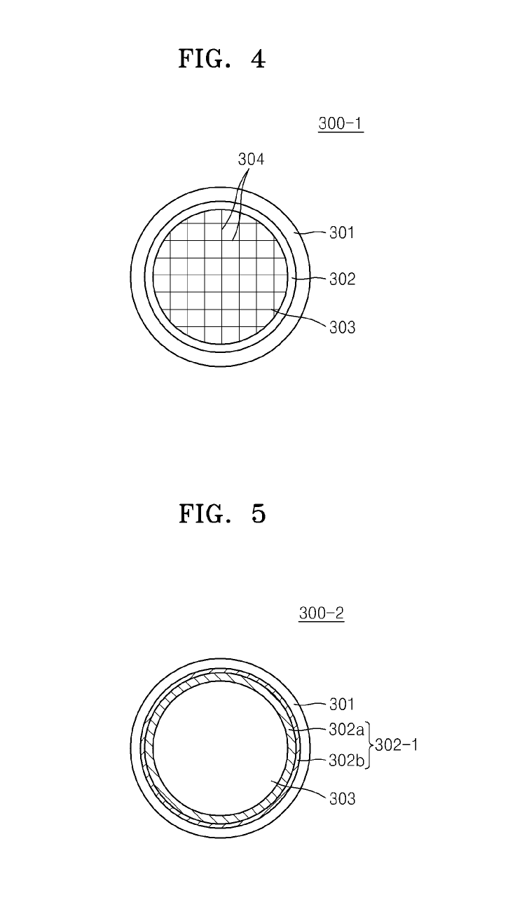

FIG. 4 is a cross-sectional view illustrating a solder ball that may be used for a semiconductor package according to an embodiment of the inventive concept.

Specifically, FIG. 4 is a schematic block diagram of a solder ball 300-1 which may be the solder ball illustrated in FIGS. 1 and 2. The solder ball 300-1 illustrated in FIG. 4 may have actually the same structure as that of the solder ball 300 illustrated in FIG. 3 except an inside of a shell 302.

The solder ball 300-1 may have a plurality of grid structures 304. That is, the inside of the shell 302 of the solder ball 300-1 may include the grid structures 304. A phase change material 303 may have the grid structures 304.

The shell 302 of the solder ball 300-1 may be a plastic shell or a metal shell (for example, a copper shell or an aluminum shell like the shell of FIG. 3. The phase change material 303 of the solder ball 300-1 may include at least one of polyethylene glycol, methylene diphenyl diisocyanate, and polyethylene glycol copolymer. When the phase change material 303 is formed in the grid structures 304, the phase change material 303 may better absorb heat generated by a chip such as the chip 20 in FIGS. 1 and 2.

FIG. 5 is a cross-sectional view illustrating a solder ball that may be used for a semiconductor package according to an embodiment of the inventive concept.

Specifically, FIG. 5 is a schematic block diagram of a solder ball 300-2. The solder ball 300-2 illustrated in FIG. 5 may have actually the same structure as those of the solder balls 300 and 300-1 illustrated in FIGS. 3 and 4 except a structure of a shell 302-1.

The shell 302-1 may be formed of a plurality of metal layers 302a and 302b that surround a phase change material 303. The shell 302-1 may be formed of the first metal layer 302a and the second metal layer 302b.

The first metal layer 302a as a plating underlayer directly formed on a surface of the phase change material 303 is used for easily forming the second metal layer 302b that will be formed later. A component of the first metal layer 302a formed on the surface of the phase change material 303 is not limited. However, metal such as gold, silver, nickel, zinc, tin, aluminum, chrome, and/or antimony may be used as the first metal layer 302a.

The first metal layer 302a may be formed of at least one of the above metals. The first metal layer 302a may be formed by a plating method. According to the present embodiment, the first metal layer 302a may be formed by an electroless plating method using nickel.

The second metal layer 302b as a conductive film directly formed on a surface of the first metal layer 302a formed on the surface of the phase change material 303 may be formed to provide conductivity to the solder ball 300-2. A component of the second metal layer 302b is not limited. However, gold, silver, copper, zinc, tin, aluminum, chrome, and/or antimony may be used as the second metal layer 302b.

The second metal layer 302b may be formed of at least one of the above metals. The second metal layer 302b may also be formed by a plating method. According to the present embodiment, the second metal layer 302b may be formed by an electroless plating method using copper or an electroplating method.

When the shell 302-1 of the solder ball 300-2 is formed of the two metal layers 302a and 302b, it is possible to better protect the phase change material 303 and increase manufacturing reliability and conductivity.

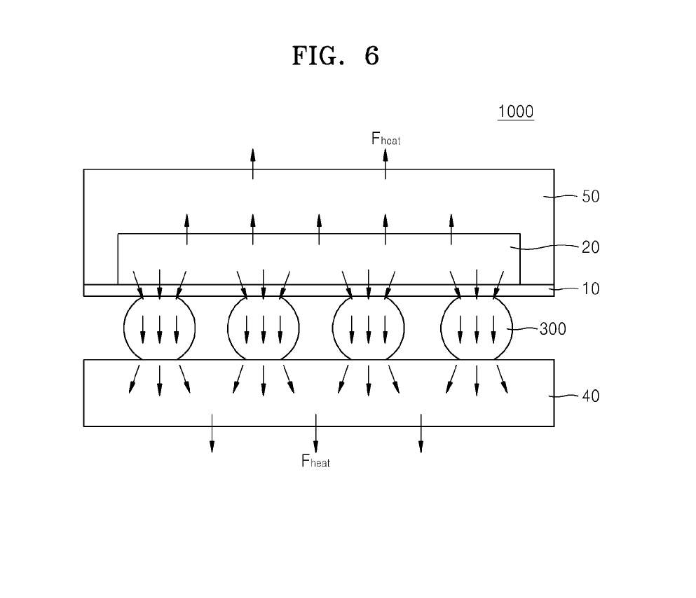

FIG. 6 is a cross-sectional view illustrating heat flow of a semiconductor package according to an embodiment of the inventive concept.

Specifically, in FIG. 6, the same elements as those of FIG. 1 are denoted by the same reference numerals. As illustrated in FIG. 6, two directions in which heat Fheat generated by the chip 20 is transmitted may exist.

In one direction, the heat is transmitted upward through the encapsulation layer 50. In the other direction, the heat is transmitted to the wiring substrate 40 through the solder ball 300. The solder ball 300 may include a solder alloy layer such as a Sn—Cu alloy or a Sn—Ag alloy. Therefore, thermal conductivity of the solder ball 300 is higher than that of the encapsulation layer 50 so that the heat generated by the chip 20 may better flow to the wiring substrate 40 through the solder ball 300.

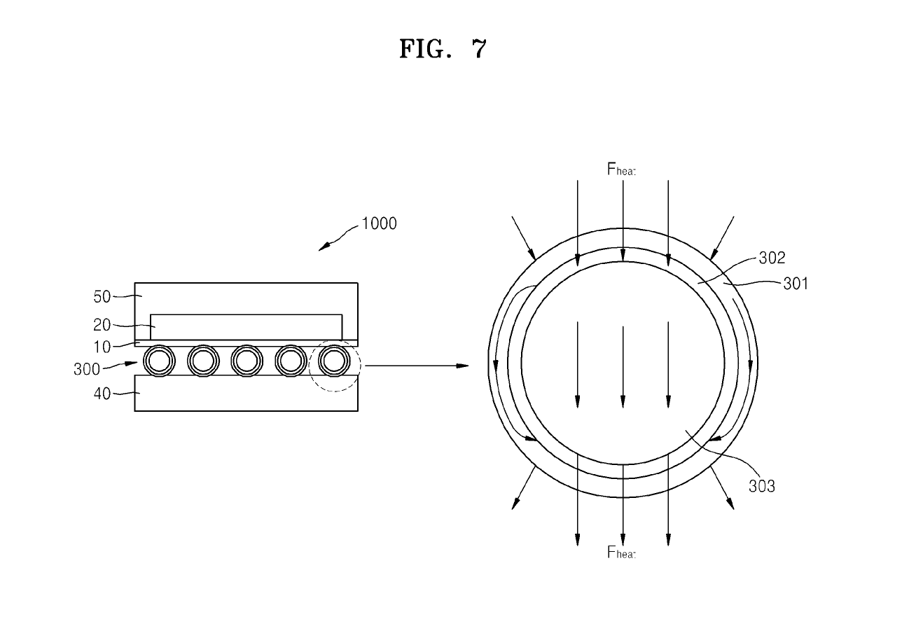

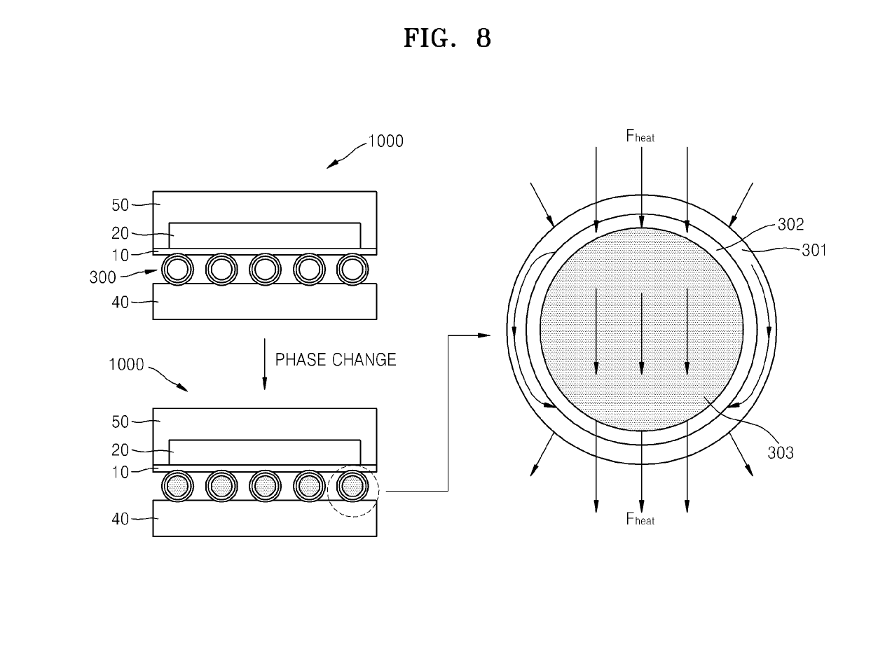

FIG. 7 is a schematic diagram illustrating a common usage state of a semiconductor package using solder balls according to an embodiment of the inventive concept. FIG. 8 is a schematic diagram illustrating a state of a semiconductor package using solder balls according to an embodiment of the inventive concept after phase changes are generated in phase change materials in the solder balls. In FIGS. 7 and 8, for convenience sake, description will be made using the solder ball 300 of FIG. 3.

Referring to FIG. 7, after the chip 20 of the semiconductor package generates heat, the heat generated by the chip 20 is mainly transmitted through the solder balls 300 since the thermal conductivity of the solder ball 300 is larger than that of the encapsulation layer 50. The right side of FIG. 7 is an enlarged view of a part (that is, the solder ball 300) surrounded by a circle of the semiconductor package on the left side.

The solder ball 300 receives the heat generated by the chip 20 so that the temperature of the phase change material 303 is increased. The solder ball 300 transmits the heat Fheat to the wiring substrate 40 as marked with arrows of FIG. 7 when the heat generated by the chip 20 is not enough to allow temperature of the phase change material 303 in the solder ball 300 to reach a phase change point (that is, phase change temperature of the phase change material 303). At this time, temperatures of the chip 20 and the wiring substrate 40 are not significantly increased so that usages or functions of the chip 20 and the wiring substrate 40 are not affected. The phase change temperature may be included in a predetermined temperature range.

On the other hand, referring to FIG. 8, a phase change is generated in the phase change material 303 in the solder ball 300 when the heat is absorbed from the chip 20 so that the temperature of the phase change material 303 in the solder ball 300 reaches the phase change temperature. The right side of FIG. 8 is an enlarged view of a part (that is, the solder ball 300) surrounded by a circle of the semiconductor package on the left side. The heat generated by the chip 20 is absorbed by the phase change material 303 in a direction marked with arrows of FIG. 8. The temperature of the phase change material 303 is maintained at the phase change point. Therefore, when the chip 20 of the semiconductor package generates a large amount of heat, the large amount of heat Fheat may not be transmitted to the wiring substrate 40, and instead, may be absorbed by the phase change material 303 in the solder ball 300 so that a temperature control characteristic of a host apparatus mounted with the semiconductor package, for example, a portable terminal may be improved.

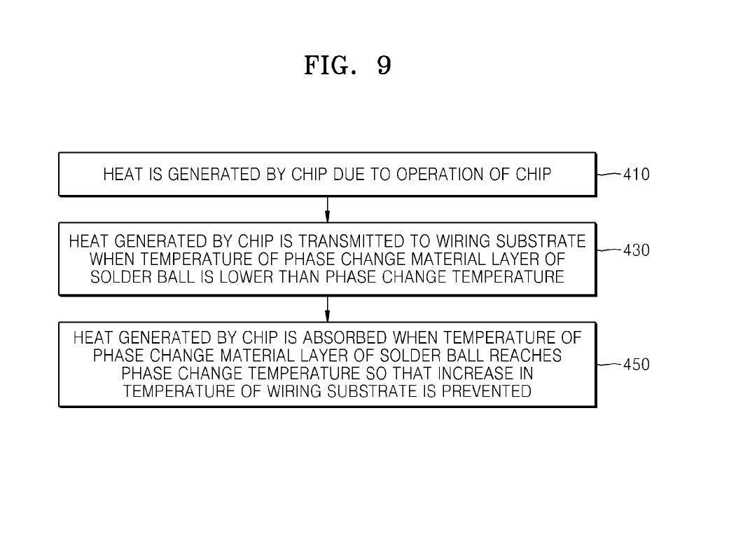

FIG. 9 is a flowchart illustrating a heat management method of a semiconductor package according to an embodiment of the inventive concept.

Specifically, the heat management method of the semiconductor package using the solder balls according to an embodiment of the inventive concept will be described with reference to FIGS. 7, 8, and 9. The heat Fheat is generated by operation of the chip 20 of the semiconductor package in operation 410. The generated heat Fheat may be transmitted through the solder balls 300. When the phase change material 303 in the shell 302 of the solder ball 300 absorbs the heat generated by the chip 20 so that the temperature of the phase change material 303 reaches temperature lower than phase transition temperature, the heat Fheat generated by the chip 20 is transmitted to the wiring substrate 40 through the solder balls 300 in operation 430.

When the phase change material 303 in the shell 302 of the solder ball 300 absorbs the heat generated by the chip 20 so that the temperature of the phase change material 303 reaches the phase transition temperature, phase change occurs in the phase change material 303 so that the phase change material 303 suppresses increase in the temperature of the wiring substrate 40 in operation 450. That is, the phase change material 303 continuously absorbs the heat generated by the chip to suppress the increase in the temperature of the wiring substrate 40. Therefore, according to the embodiment of the inventive concept, the semiconductor package may manage the heat generated by the chip 20 well.

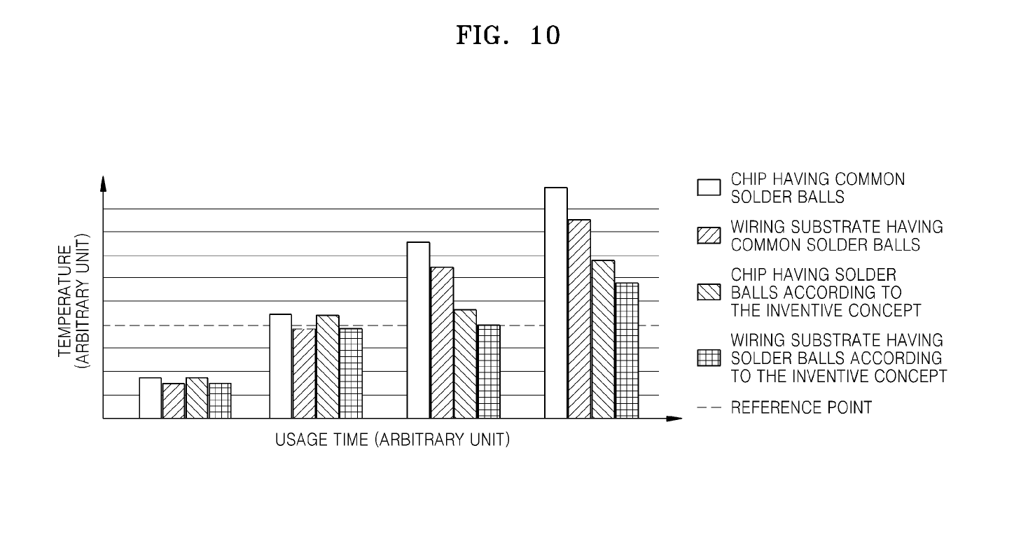

FIG. 10 is a view illustrating temperature changes of chips and wiring substrates having solder balls according to a conventional art and the inventive concept based on service (usage) time.

Specifically, in a certain time period after beginning of an operation of a chip, a change in temperature of a chip and wiring substrate using solder balls according to a conventional art is not significantly different from that of a chip and wiring substrate using solder balls according to the embodiments of the inventive concept.

However, it is noted that, with lapse of a service (usage) time, the temperature of the chip and wiring substrate using the solder balls according to the embodiments of the inventive concept is less increased than that of the chip and wiring substrate using the solder balls according to the conventional art.

This is because, while the chip and the wiring substrate using the solder balls according to the embodiments of the inventive concept absorb a large amount of heat generated by the chip due to a phase change that occurs in the phase change materials in the solder balls, in the chip and wiring substrate using the solder balls according to the conventional art, a large amount of heat generated by the chip is continuously transmitted to the wiring substrate so that the temperature of the chip and wiring substrate is increased.

Therefore, in comparison with the chip using the solder balls according to the conventional art, the solder balls according to the embodiments of the inventive concept may maintain their temperature for a longer time near a phase change point due to the phase change materials having thermal accumulation and a characteristic of maintaining phase change temperature during the phase change. In addition, as illustrated in FIG. 10, when the solder balls according to the embodiments of the inventive concept are used at temperature of no less than reference point temperature, increase in temperature may be suppressed more than when the solder balls according to the conventional art are used. Therefore, a temperature control characteristic of the chip and wiring substrate using the solder balls according to the embodiments of the inventive concept may be improved.

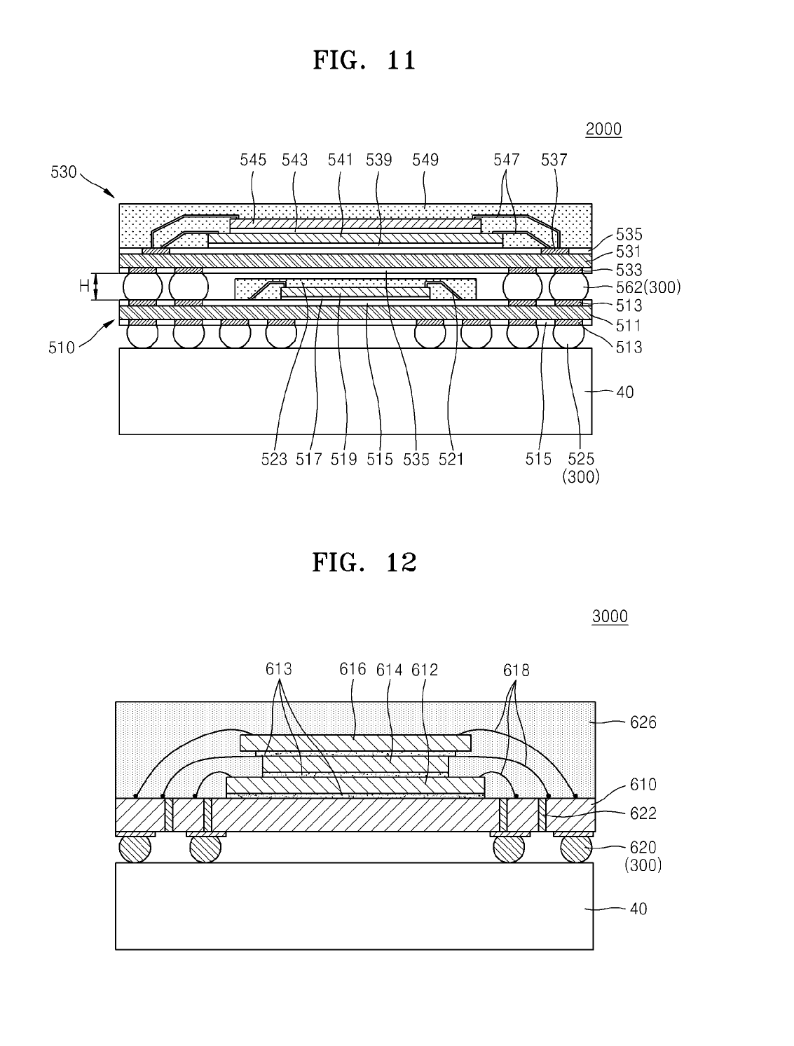

FIG. 11 is a cross-sectional view illustrating a semiconductor package according to an embodiment of the inventive concept.

Specifically, a semiconductor package 2000 according to an embodiment of the inventive concept may be almost the same as the semiconductor package 1000 of FIG. 1 except that a plurality of substrates 511 and 531 are provided, the substrates 511 and 531 are connected by second solder balls 562, and a plurality of chips 541 and 545 are formed on the upper substrate 531. The solder balls 300, 300-1, and 300-2 of FIGS. 3 to 5 may be used for the semiconductor package 2000 of FIG. 11. For convenience sake, only a reference numeral of the solder balls 300 is represented.

The semiconductor package 2000 of FIG. 11 may be a package on package (POP) type package. In the semiconductor package 2000, a lower package 510 and an upper package 530 are connected by the second solder balls 562. In the lower package 510, pads 513 and solder resist layers 515 exposing the pads 513 are formed on and under the lower substrate 511. First solder balls 525 are formed in the solder pads 513 formed under the lower substrate 511. In a center of the lower substrate 511, a first chip 519 is formed with an adhesive layer 517 interposed. The first chip 519 and the lower substrate 511 are connected by wires 521. That is, the first chip 519 is connected to the solder pads 513 of the lower substrate 511 by the wires 521 and a wiring layer (not shown) formed in the substrate 511. The first chip 519 and the wires 521 are sealed up by a first encapsulation layer 523.

In the upper package 530, bonding pads 537 and solder pads 533 are formed on and under the upper substrate 531. Solder resist layers 535 exposing the bonding pads 537 and the solder pads 533 are formed on and under the upper substrate 531. The second solder balls 562 are connected to the solder pads 533 formed under the upper substrate 531.

In a center of the upper substrate 531, a second chip 541 and a third chip 545 are formed with adhesive layers 539 and 543 interposed. The second chip 541, the third chip 545, and the bonding pads 537 of the upper substrate 531 are connected by wires 547. The second chip 541, the third chip 545, and the wires 547 are sealed up by a second encapsulation layer 549. The second chip 541 and the third chip 545 may have different sizes. The second chip 541 and the third chip 545 may be the same kind of chips or different kinds of chips.

In the semiconductor package 2000, the solder balls 300 of FIGS. 3 to 5 may be used as the first solder balls 525 formed under the lower substrate 511 and the second solder balls 562 formed under the upper substrate 531. Therefore, the solder balls 300 may effectively absorb heat generated by the chips 519, 541, and 545 to suppress increase in temperature of the wiring substrate 40 and/or the chips 519, 541, and 545.

In the semiconductor package 2000, since the second solder balls 562 formed between the lower substrate 511 and the upper substrate 531 also absorb the heat generated by the chips 519, 541, and 545, the increase in temperature of the wiring substrate 40 and/or the chips 519, 541, and 545 may be suppressed.

FIG. 12 is a cross-sectional view illustrating a semiconductor package according to an embodiment of the inventive concept.

Specifically, a semiconductor package 3000 according to an embodiment of the inventive concept may be almost the same as the semiconductor package 1000 of FIG. 1 except that a plurality of chips 612, 614, and 616 are formed on a substrate 610 and the chips 612, 614, and 616 are connected by wires 618. The solder balls 300, 300-1, and 300-2 of FIGS. 3 to 5 may be used for the semiconductor package 3000 of FIG. 12. For convenience sake, only a reference numeral of the solder balls 300 is represented.

The semiconductor package 3000 of FIG. 12 may be a stack type package in which the plurality of chips 612, 614, and 616 are stacked. In the semiconductor package 3000, the different kinds of chips 612, 614, and 616 are stacked on the substrate 610, for example, a PCB using adhesive layers 613. The different kinds of chips 612, 614, and 616 having different performances or sizes may be formed of memory circuit chips or logic circuit chips. The different kinds of chips 612, 614, and 616 are electrically connected to the substrate 610 using the wires 618.

Therefore, the different kinds of chips 612, 614, and 616 may be indirectly connected using the substrate 610. The different kinds of chips 612, 614, and 616 and the wires 618 on the substrate 610 are encapsulated by an encapsulation layer 626. Through vias 622 are formed in the substrate 610 and the through vias 622 are connected to solder balls 620 through connection pads 624. The solder balls 620 may be arranged on the wiring substrate 40.

In the semiconductor package 3000, the solder balls 300 of FIGS. 3 to 5 may be used as the solder balls 620 formed under the substrate 610. Therefore, the solder balls 300 effectively absorb heat generated by the chips 612, 614, and 616 to suppress increase in temperature of the wiring substrate 40 and/or the chips 612, 614, and 616.

In the semiconductor package 3000, since the through vias 622 are formed in the substrate 610, the heat generated by the chips 612, 614, and 616 are effectively discharged and the solder balls 300 effectively absorb the heat so that the increase in temperature of the wiring substrate 40 or the chips 612, 614, and 616 may be suppressed.

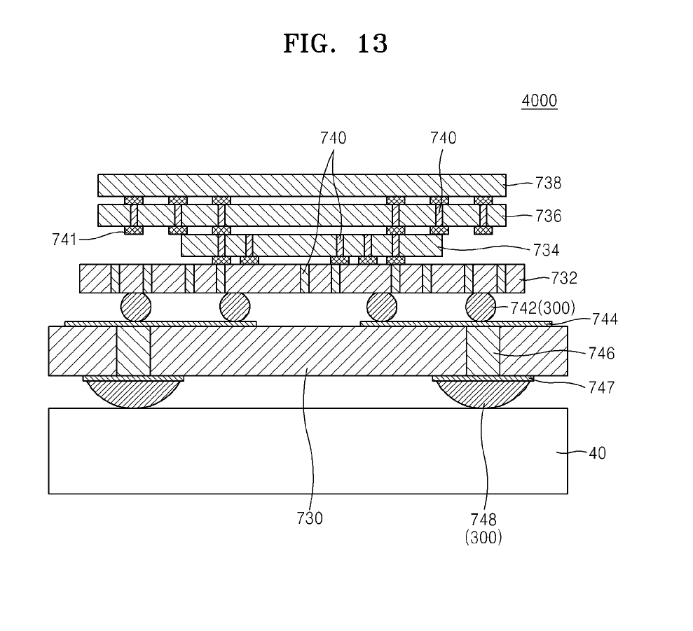

FIG. 13 is a cross-sectional view illustrating a semiconductor package according to an embodiment of the inventive concept.

Specifically, a semiconductor package 4000 according to an embodiment of the inventive concept may be almost the same as the semiconductor packages 1000 and 3000 of FIGS. 1 and 12 except that a plurality of chips 734, 736, and 738 are formed on an interpose substrate (medium substrate) 732, the chips 734, 736, and 738 are connected by through vias 740, and an encapsulation layer is not formed. The solder balls 300, 300-1, and 300-2 of FIGS. 3 to 5 may be used for the semiconductor package 4000 of FIG. 13. For convenience sake, only a reference numeral of the solder balls 300 is represented.

The semiconductor package 4000 may be a stack type package in which the plurality of chips 734, 736, and 738 are stacked. In the semiconductor package 4000, the different kinds of chips 734, 736, and 738 are stacked on a substrate 730 by a medium of the interpose substrate 732. The interpose substrate 732 may be an interposer chip. The different kinds of chips 734, 736, and 738 having different performances or sizes may be formed of memory circuit chips or logic circuit chips. The different kinds of chips 734, 736, and 738 are electrically connected to second pads 744 of the substrate 730 through first pads 741, first through vias 740, and second solder balls 742.

Therefore, the different kinds of chips 734, 736, and 738 are directly connected through the first through vias 740 and the first pads 741 formed in the respective chips. In particular, the different kinds of chips 734, 736, and 738 are directly connected through the first through vias 740 therein. The second pads 744 are connected to first solder balls 748 through second through vias 746 and third pads 747 formed in the substrate 730. The first solder balls 748 may be circular like the second solder balls 742 and may be elliptical as illustrated in FIG. 13.

In the semiconductor package 4000, since the different kinds of chips 734, 736, and 738 are directly connected without using wire bonding, performance of the semiconductor package 4000 may be improved and a size thereof may be reduced.

In the semiconductor package 4000, the solder balls 300 of FIGS. 3 to 5 may be used as the second solder balls 742 formed under the interpose substrate 732 and the first solder balls 748 formed under the substrate 730. Therefore, the solder balls 742 and 748 effectively absorb heat generated by the chips 734, 736, and 738 to suppress increase in temperature of the wiring substrate 40 and/or the chips 734, 736, and 738.

In the semiconductor package 4000, since the through vias 740 and 746 are formed in the chips 734, 736, and 738, the interpose substrate 732, and the substrate 730, the heat generated by the chips 612, 614, and 616 may be effectively discharged and the solder balls 300 effectively absorb the heat so that the increase in temperature of the wiring substrate 40 or the chips 734, 736, and 738 may be suppressed.

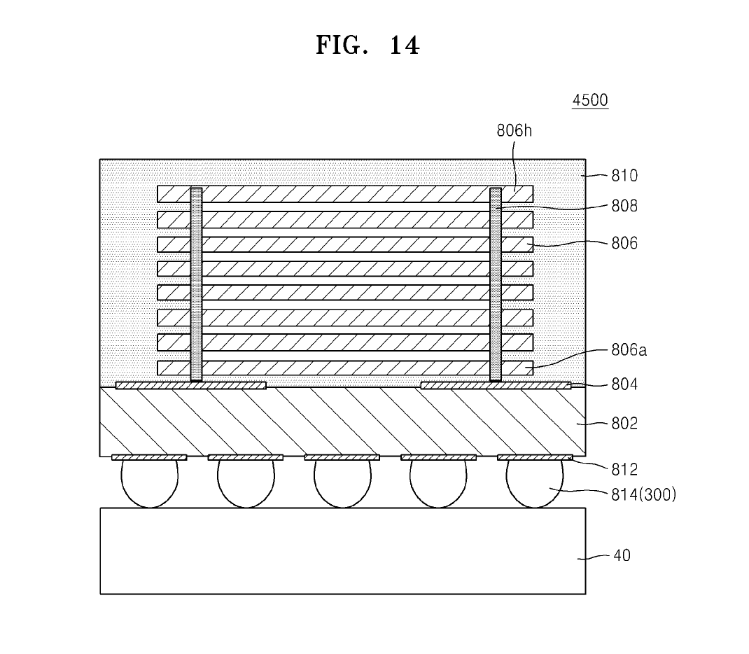

FIG. 14 is a cross-sectional view illustrating a semiconductor package according to an embodiment of the inventive concept.

Specifically, a semiconductor package 4500 according to an embodiment of the inventive concept may be almost the same as the semiconductor packages 1000 and 3000 of FIGS. 1 and 12 except that a plurality of chips 806a to 806h are formed on a substrate 802 and the chips 806a to 806h are connected by through vias 808. The solder balls 300, 300-1, and 300-2 of FIGS. 3 to 5 may be used for the semiconductor package 4500 of FIG. 14. For convenience sake, only a reference numeral of the solder balls 300 is represented.

The semiconductor package 4500 may be a stack type package in which the plurality of chips 806a to 806h are formed on the substrate 802. The substrate 802 may be a PCB. First pads 804 and second pads 812 may be formed on an upper surface and a lower surface of the substrate 802.

The plurality of chips 806a to 806h are formed on the substrate 802 and may be connected by the through vias 808. The chips 806a to 806h may be the same kind of chips having the same performance or size. The chips 806a to 806h may be formed of memory circuit chips or logic circuit chips. The chips 806a to 806h are encapsulated by an encapsulation layer 810 on the substrate 802.

In FIG. 14, among the plurality of chips 806a to 806h, for convenience sake, only reference numerals 806a and 806h are represented. The through vias 808 may be connected to the first pads 804. Solder balls 814 formed under the substrate 802 may be electrically connected to the wiring substrate 40.

In the semiconductor package 4500, the solder balls 300 of FIGS. 3 to 5 may be used as the solder balls 814 formed under the substrate 802. Therefore, the solder balls 814 effectively absorb heat generated by the chips 806a to 806h to suppress increase in temperature of the wiring substrate 40 or the chips 806a to 806h.

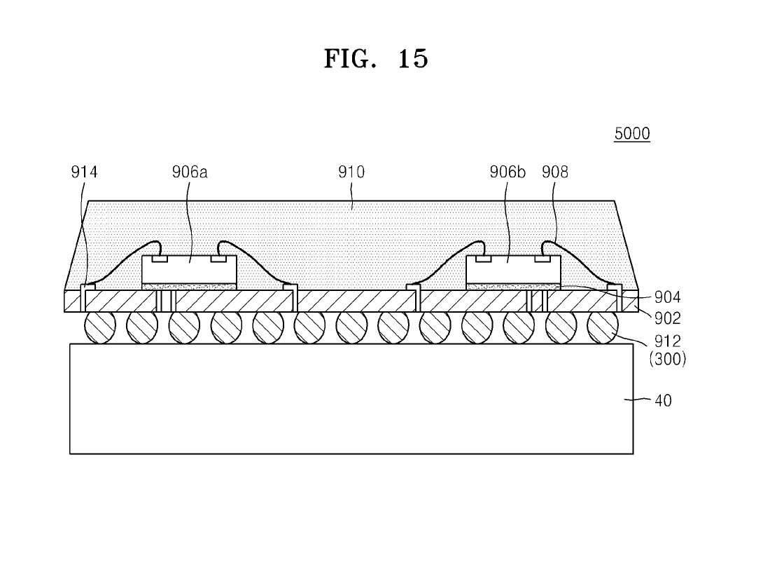

FIG. 15 is a cross-sectional view illustrating a semiconductor package according to an embodiment of the inventive concept.

Specifically, a semiconductor package 5000 according to an embodiment of the inventive concept may be almost the same as the semiconductor packages 1000, 3000, and 4500 of FIGS. 1, 12, and 14 except that a plurality of chips 906a and 906b are horizontally separated from each other to be mounted on a substrate 902 and the chips 906a and 906b are connected by wires 908. The solder balls 300, 300-1, and 300-2 of FIGS. 3 to 5 may be used for the semiconductor package 5000 of FIG. 15. For convenience sake, only a reference numeral of the solder balls 300 is represented.

The semiconductor package 5000 may be a horizontal stack type package in which the plurality of chips 906a and 906b are horizontally formed on the substrate 902. The substrate 902 may be a PCB. Through vias 904 may be formed in the substrate 902. The first chip 906a is mounted on the substrate 902. The second chip 906b horizontally separated from the first chip 906a is mounted on the substrate 902. In FIG. 15, the two chips 906a and 906b are mounted. However, the inventive concept is not limited thereto. The chips 906a and 906b may be connected to the through vias 904 by the wires 908. The chips 906a and 906b may be the same kind of chips having the same performance or size. The chips 906a and 906b may be formed of memory circuit chips or logic circuit chips. The chips 906a and 906b are encapsulated by an encapsulation layer 910 on the substrate 902.

In the semiconductor package 5000, the solder balls 300 of FIGS. 3 to 5 may be used as solder balls 912 formed under the substrate 902. Therefore, the solder balls 912 effectively absorb heat generated by the chips 906a and 906b to suppress increase in temperature of the wiring substrate 40 or the chips 906a and 906b.

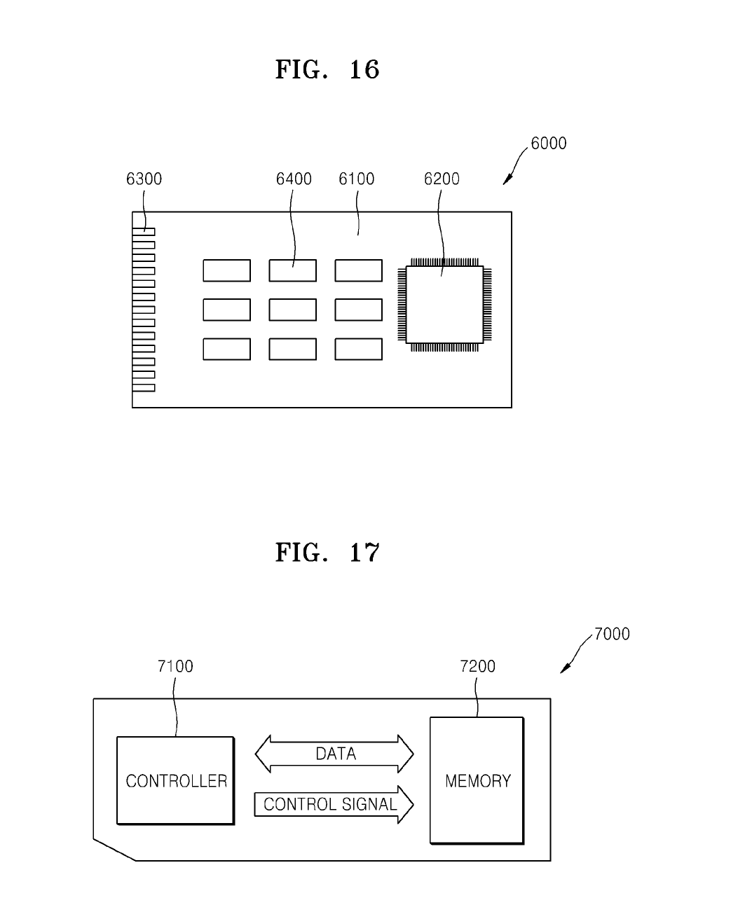

FIG. 16 is a schematic diagram illustrating a configuration of a package module using a semiconductor package according to an embodiment of the inventive concept.

Specifically, the above-described semiconductor packages 1000 to 5000 and 4500 may be applied to a package module 6000. When the above-described semiconductor packages 1000 to 5000 and 4500 are applied to the package module 6000, the wiring substrate 40 may not be required.

In the package module 6000, a plurality of semiconductor packages 6400 may be attached to a module substrate 6100. A control semiconductor package 6200 is attached to one side of the package module 6000 and an external connection terminal 6300 is positioned on the other side. The above-described semiconductor packages 1000 to 5000 and 4500 may be used as the semiconductor packages 6400 and the control semiconductor package 6200 of FIG. 16.

FIG. 17 is a schematic diagram illustrating a configuration of a card using a semiconductor package according to an exemplary embodiment of the inventive concept.

Specifically, the above-described semiconductor packages 1000 to 5000 and 4500 may be applied to a card 7000. The card 7000 may include a multimedia card (MMC) and a secure digital card (SD). The card 7000 includes a controller 7100 and a memory 7200. The memory 7200 may be a flash memory, a phase change random access memory (PRAM), or another type non-volatile memory. A control signal is transmitted from the controller 7100 to the memory 7200 and data is transmitted and received between the controller 7100 and the memory 7200.

The above-described semiconductor packages 1000 to 5000 and 4500 may be used for the controller 7100 and the memory 7200 that form the card 7000. Therefore, increase in temperature of the card 7000 with the lapse of time is suppressed so that reliability thereof may be improved.

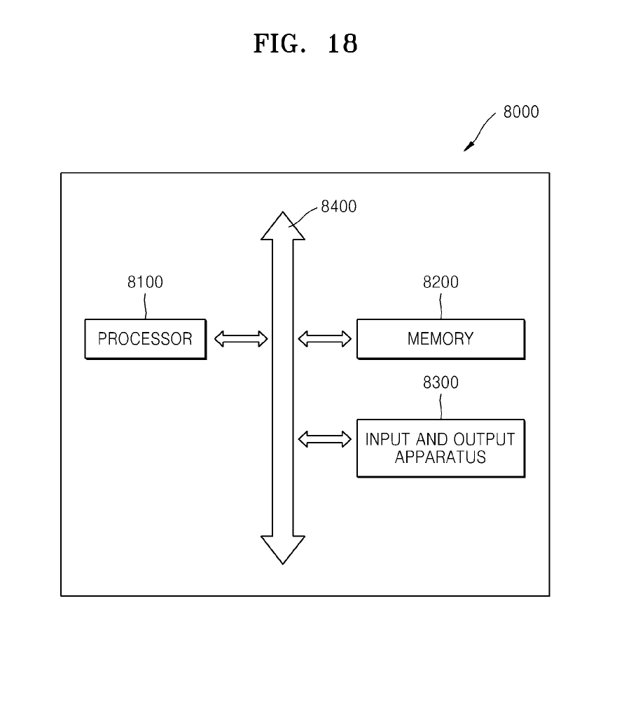

FIG. 18 is a schematic diagram illustrating a configuration of an electronic system using a semiconductor package according to an embodiment of the inventive concept.

Specifically, an electronic system 8000 according to the embodiment of the inventive concept means a computer, a mobile phone, an MPEG audio layer-3 (MP3) player, and a navigator. The electronic system 8000 includes a processor 8100, a memory 8200, and an input and output apparatus 8300. A control signal or data is transmitted and received between the processor 8100 and the memory 8200 or the input and output apparatus 8300 using a communication channel 8400.

In the electronic system 8000 according to the embodiment of the inventive concept, the semiconductor packages 1000 to 5000 and 4500 may be used for the processor 8100 and the memory 8200. Therefore, the electronic system 8000 according to the embodiment of the inventive concept implement various functions and increase in temperature of the electronic system 8000 is suppressed so that reliability thereof may be improved.

While the inventive concept has been particularly shown and described with reference to exemplary embodiments thereof, it will be understood that various changes in form and details may be made therein without departing from the spirit and scope of the following claims.

What is claimed is:

1. A semiconductor package comprising:
a chip mounted on a substrate; and
at least one first solder ball formed under the substrate,
wherein the solder ball comprises:
a solder layer;
a shell surrounded by the solder layer; and
a phase change material contained in the shell.

2. The semiconductor package of claim 1, wherein the shell is a plastic shell or a metal shell.

3. The semiconductor package of claim 1, wherein the shell is a hollow shell.

4. The semiconductor package of claim 1,
wherein an inside of the shell is formed of a grid structure, and
wherein the phase change material is formed in the grid structures of the shell.

5. The semiconductor package of claim 1, wherein the shell is formed of a plurality of metal layers surrounding the phase change material.

6. The semiconductor package of claim 1, wherein the phase change material is formed of at least one selected from a group consisting of polyethylene glycol, methylene diphenyl diisocyanate, and polyethylene glycol copolymer.

7. The semiconductor package of claim 1, wherein an encapsulation layer for sealing up the chip is formed on the substrate.

8. The semiconductor package of claim 1,
wherein a wiring substrate is further arranged under the substrate, and
wherein the chip mounted on the substrate is electrically connected to the wiring substrate through the first solder ball.

9. The semiconductor package of claim 8,
wherein an interpose substrate is further arranged on the substrate,
wherein the chip is mounted on the interpose substrate,
wherein at least one second solder ball electrically connected to the substrate is formed under the interpose substrate, and
wherein the chip mounted on the interpose substrate is electrically connected to the wiring substrate through the second solder ball and the first solder ball.

10. The semiconductor package of claim 8, wherein at least one through via electrically connected to the first solder ball is formed in the substrate.

11. The semiconductor package of claim 1,
wherein the chip is a stack type chip in which a plurality of separate chips are stacked on the substrate, and
wherein the separate chips are connected to one another by at least one through via.

12. The semiconductor package of claim 1, wherein the chip is formed of a first chip mounted on the substrate and a second chip horizontally separated from the first chip to be mounted.

13. A semiconductor package comprising:
a chip mounted on a substrate; and
at least one solder ball formed around the substrate to electrically connect the chip with an outside circuit,
wherein the solder ball comprises a phase change material.

14. The semiconductor package of claim 13, wherein the phase change material is configured to change its physical state between a solid and a liquid in a predetermined temperature range.

15. The semiconductor package of claim 14, wherein the phase change material is formed of at least one selected from a group consisting of polyethylene glycol, methylene diphenyl diisocyanate, and polyethylene glycol copolymer.

16. The semiconductor package of claim 13, wherein the phase change material is configured to absorb and store heat generated by the chip without transferring the heat outside the solder ball until a temperature of the phase change material reaches a predetermined temperature.

17. The semiconductor package of claim 16, further comprising at least one via formed in the substrate to connect the chip to the solder ball.

18. A semiconductor package comprising:
a first chip mounted on a first substrate;
at least one first solder ball formed on the first substrate;
a second substrate arranged on the first solder ball;
a second chip mounted on the second substrate; and
at least one second solder ball formed on a rear surface of the first substrate,
wherein at least one solder ball among the first solder ball and the second solder ball comprises:
a solder layer;
a shell surrounded by the solder layer; and
a phase change material contained in the shell.

19. The semiconductor package of claim 18,
wherein a first encapsulation layer for sealing up the first chip is formed on the first substrate, and
wherein a second encapsulation layer for sealing up the second chip is formed on the second substrate.

20. The semiconductor package of claim 19,
wherein a wiring substrate is further arranged under the first substrate, and
wherein the first chip and the second chip mounted on the first substrate and the second substrate, respectively, are electrically connected to the wiring substrate through the first and second solder balls.
